(19) United States
(12) Patent Application Publication
(10) Pub. No.: US 2005/0205874 A1
(43) Pub. Date: Sep. 22, 2005

(54) Phosphor material and white light-emitting device using the same

(76) Inventors: Ru-Shi Liu, Hsinchu Hsien (TW); Yi-Shan Lin, Nan Tou Hsien (TW); Liang-Sheng Chi, Yun-Lin Hsien (TW); Chien-Yuan Wang, Kaohsiung Hsien (TW)

Correspondence Address: BIRCH STEWART KOLASCH & BIRCH, PO BOX 747, FALLS CHURCH, VA, 22040-0747, US

(21) Appl. No.: 10/803,951

(22) Filed: Mar. 19, 2004

(51) Int. Cl. H01L 27/15

(52) U.S. Cl. 257/79

(57) ABSTRACT

A white light-emitting device comprising a blue-violet or blue LED and a phosphor material capable of emitting a yellow-green to orange-yellow light upon excitation by the light emitted by the LED. The light from the LED and the phosphor material are mixed in an appropriate ratio to produce a white light. The phosphor material has a general formula (YₓM_{y}Ce_{z})Al₅O₁₂, where x+y=3, x, y≠0, 0.5>z>0, and M is selected from the group consisting of Tb, Lu, and Yb, with (YₓM_{y})Al₅O₁₂ serving as a host and Ce as an activator. By changing the composition of the metal elements in the host, the crystal field is modulated to thereby alter the energy level of the excited state to which the activator is transferred upon irradiation by a specific wavelength of light, leading to the change in the emitting wavelength of the phosphor material.

### FIELD OF THE INVENTION

The present invention relates to high-brightness white light-emitting device, especially to a high-brightness white light-emitting device with a purple-blue light or blue light emitting diodes in combination with suitable phosphor to provide white light.

### BACKGROUND OF THE INVENTION

It is known that the white light is mixed light of different colors. The white light, which is sensed by human eye as white color, at least includes two or more colors of light having different wavelengths. For example, when human eye is stimulated, at the same time, by the Red, Green, and Blue colors of light, or by blue light and yellowish light, a white color is sensed. Accordingly, there have been three major approaches to the formation of white light for now. The first is using R/G/B LEDs. By controlling the current passing the LED to generate white light. The second is using yellow/blue LEDs to generate white light. These two prior art methods has a common drawback in that when quality of one of the plural LEDs deteriorates, an accurate white light is no longer obtained. Furthermore, using plural LEDs is costly. Another known approach is using InGaN LED, which generates blue light that can be absorbed by phosphor dye or powders to emit yellowish light, that is mixed with blue light to produce white light.

In 1996, a Japanese company, Nichia Kagaku Kogyo Kabushiki Kaisha (Tokushima), which is also known as “Nichia Chemical” on the market, disclosed a method for generating white light by using a blue light emitting diode (LED) that emits blue light absorbed by a fluorescent material to emit yellowish light. The yellowish light is diffused and mixed with blue light to eventually generate high brightness white light. This new technique has ushered a new era of white LED illumination and is believed that will soon replace the conventional fluorescent lamps in the near future. In Taiwan Patent No. 383508 and also in U.S. Pat. No. 5,998,925, assigned to Nichia Kagaku Kogyo Kabushiki Kaisha, disclose a yellow light YAG:Ce fluorescent powder, which has a general formula (Y_{1-p-q-r}GdₚCe_{q}Smᵣ)₃(Al₁₋ₛGaₛ)₅O₁₂, where 0≦p≦0.8, 0.003≦q≦0.2, 0.003≦r≦0.08, 0≦s≦1.

However, so far, since most commercial InGaN type blue LED is made by using metal organic chemical vapor deposition (MOCVD), only blue LED with fixed wavelength can be obtained. There has been a strong need for providing a series of yellow light phosphor powders capable of modulating emitted blue light wavelengths in a range of from 430 nm to 490 nm.

The emitting wavelength of the conventional phosphor is adjusted by added with a hetero ion. For example, the phosphor with general formula Tb₃Al₅O₁₂:Ce can emit 556 nm yellow light. But, after adding Gd into this formula, the resulting Tb₃Al₅O₁₂: Ce formula can red shift the main wavelength to 556 nm.

However, in above-mentioned adjusting method, the hetero ion occupies only few ration of the overall phosphor. Serious deviation will occur if only slight error in the weight of the hetero ion.

### SUMMARY OF THE INVENTION

It is an object of the present invention to provide a phosphor material used with a blue LED to manufacture a white light-emitting device, wherein the emitting color of the phosphor material can be changed to adapt the used blue LED.

In the present invention, a yellow phosphor material has a host matrix with a formula (YₓM_{y})Al₅O₁₂, wherein x+y=3, x, y≠0, 0.5>z>0, and M is selected from the group consisting of Tb, Lu, and Yb. By changing the composition of the metal elements in the host, the crystal field thereof may be modulated to thereby alter the energy level of the excited state to which the activator is transferred upon irradiation by a specific wavelength of light, leading to the change in the emitting wavelength of the phosphor material.

In a white light-emitting device using above-mentioned phosphor, an LED with a purple-blue light or blue light is used as exciting light source and the phosphor will emit yellow-green light or orange-yellow light of domination wavelength between 560 to 590 nm. The light emitted from LED and phosphor are mixed to provide a white light.

The short-wavelength blue LED has more difficult manufacture than the long-wavelength blue LED. The wavelength-adjustable property of the phosphor according to the present invention can advantageously facilitate the use of blue LED in long-wavelength regime. For example, the phosphor can be advantageously excited by blue LED of 470 nm with higher efficiency instead of 460 nm blue LED.

In the present invention, the luminescent wavelength of phosphor is adjusted by modulating the crystal field of the host matrix of used phosphor instead of changing the amount of hetero ions. The added amount of the hetero ions is too small to be precisely controlled. On the contrary, the process of the present invention is simpler and more stable.

The various objects and advantages of the present invention will be more readily understood from the following detailed description when read in conjunction with the appended drawing, in which:

### BRIEF DESCRIPTION OF DRAWING

FIG. 1 shows relative position of metal d orbit and relative coordinate electrons;

FIG. 2 shows the energy diagram of phosphor with Y or Tb as host matrix and with different Ce amount;

FIG. 3 shows an excitation spectrum (A) and emission spectrum (B1, B2) of the (Y_{1.80}Tb_{1.20}Ce_{0.05})Al₅O₁₂ phosphor.

FIG. 4 is the emission spectrum of the phosphor according to the present invention with different Tb and Y ratios; and

FIG. 5 shows the CIE coordinate of the phosphor according to the present invention with different Tb and Y ratios.

### DETAILED DESCRIPTION OF THE INVENTION

Ion the present invention, the Y ions in the conventional (Y₁₋ₓCeₓ)Al₅O₂ yellow phosphor is replaced by other metal ions such as Tb, Lu, and Yb, which have similar valence number and ion radius as those of Y. The added ions can easily substitute into the host matrix to form a solid-state solution of single phase. The emitting wavelength of the phosphor can be adjusted by changing the added ion ratio. Therefore, the wavelength-adjustable property of the phosphor according to the present invention can advantageously facilitate the use of blue LED of different wavelengths.

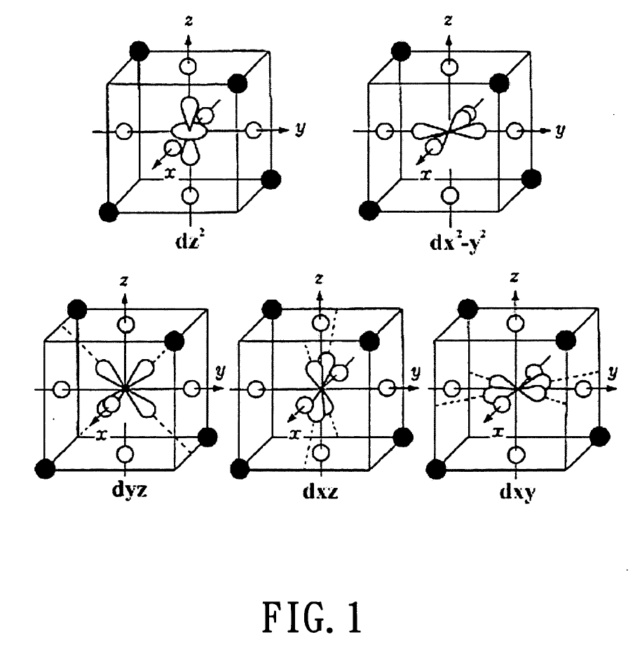

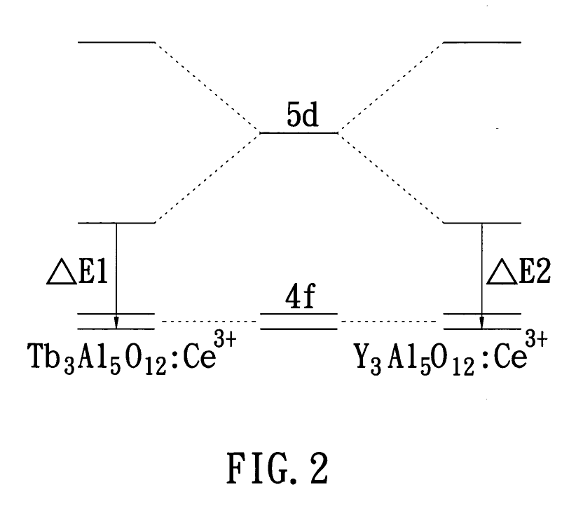

With reference to FIGS. 1 and 2, the principle for modulating the emitting wavelength of the phosphor according to the present invention will be described below.

The pure YAG has a bandgap (energy difference between conduction band and valence band) similar to the energy of UV light. Therefore, light in visible regime will not be absorbed by YAG and the YAG powder will be white color. The YAG added with rare earth ions will absorb visible light and then emits light of longer wavelength. For example, the YAG powder doped with Ce³⁺ to replace Y. i.e., (Y₃₋ₓCeₓ) Al₅O₁₂ or YAG: Ce³⁺ will absorb 470 nm blue light and then emits yellow light. The YAG powder doped with Tb³⁺ to replace Y will emit green light. The YAG powder doped with Eu³⁺ to replace Y will emit red light. The YAG powder doped with Bi³⁺ to replace Y will emit blue light.

In the present invention, the emitted wavelength of the phosphor is adjusted by changing the structure of the host matrix rather than doping different ions into the host matrix. The induced crystal field will be different for the same ion in host matrix of different structure. The crystal field theory is based on the assumption that energy split in complex or crystal compund is modeled by point chgarge. That is, the metal ion and ambience are sssumed to be dimensionless point charge and the crystal field theory is is used to calculate the action to electron in d orbit.

FIG. 1 shows the action between d orbit and surrounding configuration electrons for center metal in octahedron (Oₕ and tetrahedron (T_{d}), wherein solid dot is for the case of tetrahedron and hollow dot is for the case of octahedron. According the group theory, d orbit has t_{2g} and e_{g} phases. For octahedron, d_{xy} [symbol] d_{yz} and d_{xz} belong to t_{2g} phase, and dₓ²_{-y}² and d_{z}² belong to e_{g} phase. The electron density on the sphere is 90%, there is static repulsive force between the orbital electron and coordinate electron surround it.

As can be seen from FIG. 1, the coordinate charge in e_{g} phase of d orbit (dₓ²_{-y}² and d_{z}²) has larger repulsive force and produces larger energy split than the t_{2g} phase of d orbit (d_{xy} [symbol] d_{yz} and d_{xz}) The electronic configuration of Ce³⁺ is [Xe]4f¹, the 4f orbit thereof is split to ²F_{5/2} and ²F_{7/2} due to spin-orbital coupling, and the 5d orbit is split due to crystal field.

Taking Tb as example, the left side and right side of FIG. 2 show the energy states of Tb and Y host matrix, respectively. The crystal field of Ce³⁺:Tb₃Al₅O₁₂ has larger amount than the crystal field of Ce³⁺:Y₃Al₅O₁₂ The 5d energy split of Ce³⁺ will be increased when Y is replaced by Tb. The energy gap between 5d and 4f levels is reduced, i.e., ΔE1<ΔE2, to red shift the emitted light.

In the present invention, the phosphor material has a general formula (YₓM_{y}Ce_{z})Al₅O₁₂, where x+y=3, x, y≠0, 0.5>z>0, and M is selected from the group consisting of Tb, Lu, and Yb, with (YₓM_{y})Al₅O₁₂ serving as a host and Ce as an activator. By changing the composition of the metal elements in the host, the crystal field thereof may be modulated to thereby alter the energy level of the excited state 5d and 4f ground state upon irradiation by a specific wavelength of light, leading to the change in the emitting wavelength of the phosphor material.

The phosphor material according to the present invention can be excited by a purple-blue light or blue light emitting diodes with wavelengths between 430 nm to 500 nm and then emits yellow-green light to orange-yellow light with domination wavelength between 560 to 590 nm, thus mixing into a white light with light from LED.

The above-mentioned phosphor according to the present invention has adjustable emitting wavelength caused by variation in crystal field and can be used with blue LED of various wavelength to implement a white light-emitting device. Moreover, the phosphor according to the present invention can be prepared by simple solid-state reaction process.

According to the method disclosed in this application, the purple-blue or blue light is generated by low power consumption light-emitting diodes in combination with a suitable phosphor material. After packaging, a high brightness white LED with good light properties operated at very low voltage is obtained.

The phosphor according to the present invention can be prepared by solid-state reaction process, Sol-Gel method and co-precipitation method and is exemplified by M=Tb as following:

### A. EXAMPLE 1

1. Preparing mixture for forming a composition having a stoichiometry of (Y_{1.80}Tb_{1.20}Ce_{0.05})Al₅O₁₂ by mixing and grinding Y(NO₃)₃·6H₂O of 3.1750 g, Al(NO₃)₃·9H₂O of 8.6400 g, Ce(NO₃)₃·6H₂O of 0.1000 g and Tb₄O₇ of 8.6400 g.

2. Placing thus-produced mixture in a crucible and heating the mixture for calcination in air at 1000° C. with a heating rate of 5° C./min for 24 hours and followed by cooling down at a cooling rate of 5° C./min to form intermediate powders.

3. Grinding the calcined powder and then placing the calcined powder again in the crucible for sintering in air for 24 hours with temperature ramp and drop of 5° C./min.

4. Placing the sintered powder in a H₂/N₂ (5%/95%) reductive ambient at 1500° C. for 12 hours for reduction. This reduces Ce⁴⁺ to Ce³⁺. It is noted that this step, which can improve light brightness, is optional.

### B. EXAMPLE 2

1. Preparing mixture for forming a composition having a stoichiometry of (Y_{2.375}Tb_{0.625} Ce_{0.05})Al₅O₁₂ by mixing and grinding Y(NO₃)₃·6H₂O of 4.1897 g, Al(NO₃)₃·9H₂O of 8.6400 g, Ce(NO₃)₃·6H₂O of 0.1000 g and Tb₄O₇ of 0.2836 g.

2. Placing thus-produced mixture in a crucible and heating the mixture for calcination in air at 1000° C. with a heating rate of 5° C./min for 24 hours and followed by cooling down at a cooling rate of 5° C./min to form intermediate powders.

3. Grinding the calcined powder and then placing the calcined powder again in the crucible for sintering in air for 24 hours with temperature ramp and drop of 5° C./min.

4. Placing the sintered powder in a H₂/N₂ (5%/95%) reductive ambient at 1500° C. for 12 hours for reduction.

### C. COMPARISON EXAMPLE

1. Preparing mixture for forming a composition having a stoichiometry of (Y₃Ce_{0.05}) Al₅O₁₂ by mixing and grinding Y(NO₃)₃·6H₂O of 5.2923 g, Al(NO₃)₃·9H₂O of 8.6400 g, and Ce(NO₃)₃·6H₂O of 0.1000 g.

2. Placing thus-produced mixture in a crucible and heating the mixture for calcination in air at 1000° C. with a heating rate of 5° C./min for 24 hours and followed by cooling down at a cooling rate of 5° C./min to form intermediate powders.

3. Grinding the calcined powder and then placing the calcined powder again in the crucible for sintering in air for 24 hours with temperature ramp and drop of 5° C./min.

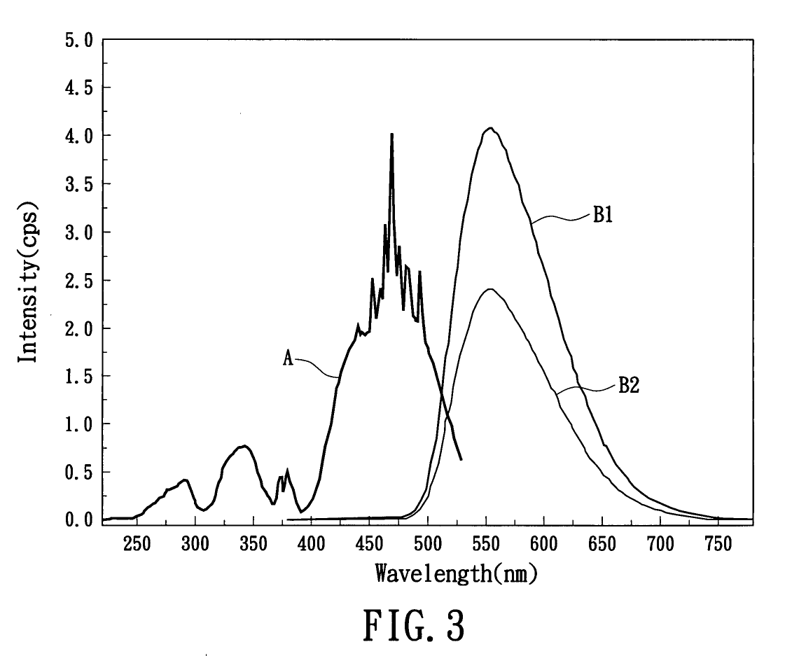

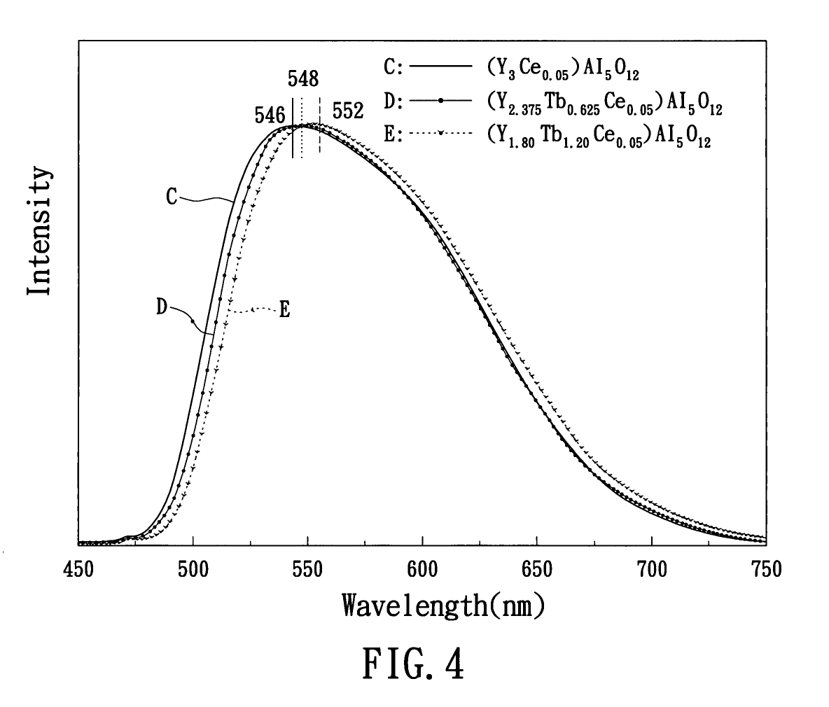

4. Placing the sintered powder in a H₂/N₂ (5%/95%) reductive ambient at 1500° C. for 12 hours for reduction. The phosphors prepared in above three exampled are then cooled and ground to powder. The spectral properties are then measured with excitation spectrum shown in FIGS. 3 to 5.

FIG. 3 shows the excitation spectrum A and emission spectrums B1, B2 for the (Y_{1.80}Tb_{1.20}Ce_{0.05})Al₅O₁₂ phosphor material according to the present invention, wherein the spectrum B1 is excited by 470 nm blue light and the spectrum B2 is excited by 460 nm blue light. As can be seen from this figure, the (Y_{1.80}Tb_{1.20}Ce_{0.05})Al₅O₁₂ phosphor material excited by 470 nm blue light has stronger emission than (Y_{1.80}Tb_{1.20}Ce_{0.05})Al₅O₁₂ phosphor material excited by 460 nm blue light. Therefore, the phosphor material can be advantageously excited by longer wavelength light.

FIG. 3 shows the emission spectrum of phosphor according to the present invention with different Tb and Y ratios, wherein curve C is the emission spectrum corresponding to the phosphor with formula (Y₃Ce_{0.05})Al₅O₁₂ according to comparison example, curve D is the emission spectrum corresponding to the phosphor with formula (Y_{2.375}Tb_{0.625} Ce_{0.05})Al₅O₁₂ according to example 2, and curve E is the emission spectrum corresponding to the phosphor with formula (Tb_{2.95}Ce_{0.05})Al₅O₁₂ according to example 1.

More particularly, the curve E is corresponding to the phosphor without adding Tb, i.e., (Y₃Ce_{0.05})Al₅O₁₂; and the emission spectrum thereof has a peak at 546 nm after excitation by 470 nm blue light. The curve D is corresponding to the phosphor added certain Tb, i.e., (Y_{2.375}Tb_{0.625} Ce_{0.05})Al₅O₁₂; and the emission spectrum thereof has a peak at 548 nm after excitation by 470 nm blue light. The curve C is corresponding to the phosphor added more Tb, i.e., (Y_{1.80}Tb_{1.20}Ce_{0.05})Al₅O₁₂; and the emission spectrum thereof has a peak at 552 nm. That is, the addition of Tb will red-shift the emission spectrum, and the effect of the variation of metal ion diameter can be validated.

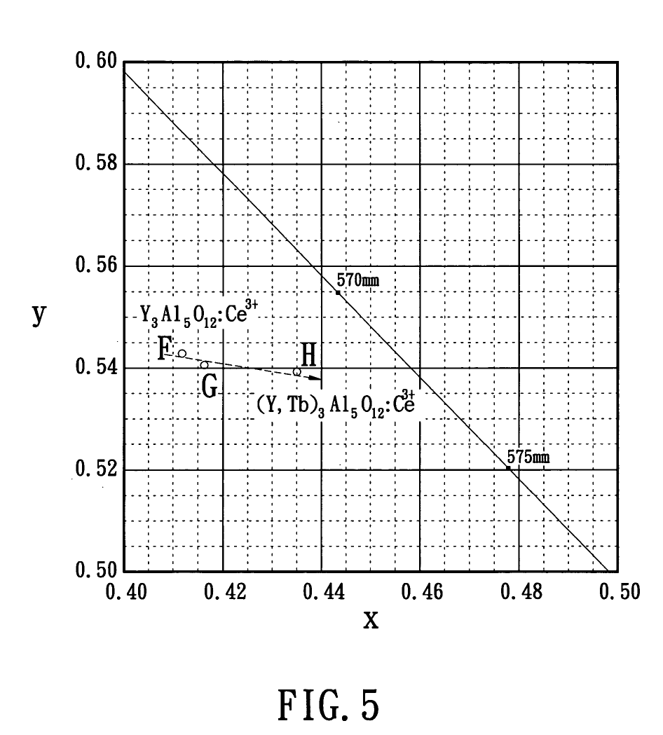

FIG. 5 shows the CIE coordinate of phosphor with different Y and Tb ratios, wherein point F is corresponding to the curve C, point G is corresponding to the curve D and point H is corresponding to the curve E. As can be seen in this chart, the CIE coordinate is moved toward longer wavelength regime as the ratio of Tb is increased.

Although the present invention has been described with reference to the preferred embodiment therefore, it will be understood that the invention is not limited to the details thereof. Various substitutions and modification s have suggested in the foregoing description, and other will occur to those of ordinary skill in the art. Therefore, all such substitutions and modifications are intended to be embrace within the scope of the invention as defined in the appended claims.

1. A white light-emitting device, comprising
a light-emitting diode for emitting a first light with predetermined wavelength; and
a phosphor receiving the light of the light-emitting diode and emitting a second light of different wavelength for mixing with the first light and forming a white light;
wherein the phosphor material has a general formula (YₓM_{y}Ce_{z})Al₅O₁₂, where x+y=3, x, y≠0, 0.5>z>0, and M is selected from the group consisting of Tb, Lu, and Yb, with (YₓM_{y})Al₅O₁₂ serving as a host and Ce as an activator, the ratio of M is adjusted to change a crystal field in the host matrix, thus changing the wavelength of the second light.

2. The white light-emitting device as in claim 1, wherein the light-emitting diode has a domination wavelength between 430 nm and 500 nm.

3. The white light-emitting device as in claim 1, wherein the phosphor has a domination wavelength between 560 nm and 590 nm.

4. The white light-emitting device as in claim 1, wherein the phosphor is made from a group consisting of metal oxide, nitrate, metal organic compound and metal salt.

5. The white light-emitting device as in claim 1, wherein the phosphor is made by a solid-state reaction process.

6. The white light-emitting device as in claim 1, wherein the phosphor is made by a chemical process.

7. The white light-emitting device as in claim 6, wherein the chemical process is a citrate sol-gel process.

8. The white light-emitting device as in claim 6, wherein the chemical process is a co-precipitation process.

9. A phosphor used for a white light-emitting device and receiving a light with a first wavelength of the light-emitting diode and emitting light with a second wavelength different to the first wavelength and mixed with the light of the light-emitting diode to form a white light, the phosphor having a host matrix of (TbₓM_{y})Al₅O₁₂ and using Ce as activator,
wherein the phosphor material has a general formula (YₓM_{y}Ce_{z})Al₅O₁₂, where x+y=3, x, y≠0, 0.5>z>0, and M is selected from the group consisting of Tb, Lu, and Yb, with (YₓM_{y})Al₅O₁₂ serving as a host and Ce as an activator, the ratio of M is adjusted to change a crystal field in the host matrix, thus changing the wavelength of the second light.

10. The phosphor as in claim 9, wherein the light-emitting diode has a domination wavelength between 430 nm and 500 nm.

11. The phosphor as in claim 9, wherein the phosphor has a domination wavelength between 560 nm and 590 nm.

12. The phosphor as in claim 9, wherein the phosphor is made from a group consisting of metal oxide, nitrate, metal organic compound and metal salt.

13. The phosphor as in claim 9, wherein the phosphor is made by a solid-state reaction process.

14. The phosphor as in claim 9, wherein the phosphor is made by a chemical process.

15. The phosphor as in claim 14, wherein the chemical process is a citrate sol-gel process.

16. The phosphor as in claim 14, wherein the chemical process is a co-precipitation process.
